(19) United States
(12) Patent Application Publication
(10) Pub. No.: US 2025/0359397 A1
(43) Pub. Date: Nov. 20, 2025

(54) LIGHT-EMITTING DIODE AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Zhuangshi LIU, Tianjin (CN); Huanshao KUO, Tianjin (CN); Yuren PENG, Tianjin (CN)

(21) Appl. No.: 19/207,351

(22) Filed: May 14, 2025

(30) Foreign Application Priority Data
May 14, 2024 (CN) 202410598679.2

(51) Int. Cl. H10H 20/819; H10H 20/816; H10H 20/831; H10H 20/841; H10H 20/85; H10H 20/857

(52) U.S. Cl. CPC H10H 20/819; H10H 20/816; H10H 20/831; H10H 20/841; H10H 20/8508; H10H 20/857

(57) ABSTRACT

In a light-emitting diode, a projection of a current spreading layer in a direction from a first surface to a second surface does not overlap with a projection of a first electrode in the direction from the first surface to the second surface, the projection of the current spreading layer in the direction from the first surface to the second surface has a minimum distance from a geometric center of a projection of a pad electrode in the direction from the first surface to the second surface, and a projection of a first ohmic contact layer in the direction from the first surface to the second surface is located outside a circumference centered at the geometric center of the projection of the pad electrode in the direction from the first surface to the second surface with a radius of the minimum distance.

### CROSS-REFERENCE TO RELATED APPLICATION

This application claims priority to Chinese Patent Application No. 202410598679.2, filed May 14, 2024, which is herein incorporated by reference in its entirety.

### TECHNICAL FIELD

The disclosure relates to the technical field of semiconductor optoelectronic devices, and more particularly to a light-emitting diode (LED) and a light-emitting device.

### BACKGROUND

An LED is a semiconductor device that emits light by releasing energy during carrier recombination. Due to its advantages such as a higher luminous intensity, a higher efficiency, a smaller size, and a longer service life, the LED is considered one of the most promising light sources currently available.

LEDs existing in the related art include a horizontal-type LED and a vertical-type LED. The vertical-type LED has electrodes placed on a top and a bottom of a chip, allowing current to flow vertically through the LED chip. Compared to the horizontal-type LED, the vertical-type LED can effectively solve problems such as light absorption, current crowding, and poor heat dissipation caused by an epitaxial growth substrate. When the current is injected into the electrode placed on the top of the chip, it is transferred to several current transmission blocks within the chip and then flows to the electrode placed on the bottom of the chip, ensuring uniform current distribution and avoiding current concentration. To enhance the electrical contact between the electrode and a semiconductor structure, an ohmic contact layer, typically made of gallium phosphide (GaP) or gallium arsenide (GaAs), is usually placed between the semiconductor structure and the electrode. However, this ohmic contact layer has a significant light absorption effect, which negatively impacts light emission efficiency of the LED.

For the vertical-type LED, to improve the light emission efficiency, a patterned current spreading layer is typically designed in a light-emitting region to reduce the light absorption by the ohmic contact layer and the current spreading layer. However, the patterned current spreading layer can cause current crowding, concentrating the current near electrode extension strips on a side of an N-type semiconductor layer. This effect becomes more pronounced as the electrode extension strips on the side of the N-type semiconductor layer get closer to a wire bonding electrode or a pad electrode, leading to non-uniform light emission across the chip.

### SUMMARY

In response to problems of non-uniform current spreading and light absorption by an ohmic contact layer in an LED chip in the related art, the disclosure provides an LED and a light-emitting device. In the LED of the disclosure, a projection of a current spreading layer in a direction from a first surface to a second surface does not overlap with a projection of a first electrode in the direction from a first surface to a second surface. In addition, the projection of the current spreading layer in the direction from the first surface to the second surface has a minimum distance from a geometric center of a projection of a pad electrode of the first electrode in the direction from the first surface to the second surface. A projection of a first ohmic contact layer is located outside a circumference centered at the geometric center of the projection of the pad electrode of the first electrode in the direction from the first surface to the second surface with a radius of the minimum distance, that is, the first ohmic contact layer is disposed below extension strips of the first electrode. As a result, an area of the first ohmic contact layer on a side of an N-type semiconductor layer is reduced, which decreases light absorption and improves the uniformity of current spreading in the LED. This also reduces a risk of the pad electrode falling off during a packaging process, thereby enhancing the reliability of the LED.

The LED includes a semiconductor epitaxial stacked layer, a first electrode, an ohmic contact layer and a current spreading layer.

The semiconductor epitaxial stacked layer has a first surface and a second surface that are opposite to each other, the semiconductor epitaxial stacked layer includes an N-type layer, an active layer and a P-type semiconductor layer in a direction from the first surface and the second surface, and the first surface is a light-emitting surface.

The first electrode is disposed on the first surface, the first electrode includes a pad electrode and multiple extension strips, and the multiple extension strips extend from edges of the pad electrode and are spaced from each other.

The first ohmic contact layer is disposed between the multiple extension strips and the N-type semiconductor layer, and the first ohmic contact layer is covered by the multiple extension strips.

The current spreading layer is disposed on the second surface, and the current spreading layer has a patterned structure.

A projection of the current spreading layer in the direction from the first surface to the second surface does not overlap with a projection of the first electrode in the direction from the first surface to the second surface, the projection of the current spreading layer in the direction from the first surface to the second surface has a minimum distance from a geometric center of a projection of the pad electrode in the direction from the first surface to the second surface, and a projection of the first ohmic contact layer in the direction from the first surface to the second surface is located outside a circumference centered at the geometric center of the projection of the pad electrode in the direction from the first surface to the second surface with a radius of the minimum distance.

As described above, by disposing the first ohmic contact layer on the side of the N-type semiconductor layer outside the circumference centered at the geometric center of the projection of the pad electrode in the direction from the first surface to the second surface with the radius of the minimum distance (i.e., below the multiple extension strips of the first electrode), the area of the first ohmic contact layer is reduced. Therefore, the absorption of light emitted by the active layer is decreased. Moreover, the above configuration places the first ohmic contact layer below the multiple extension strips of the first electrode, with no first ohmic contact layer beneath the pad electrode. As a result, current crowding near the pad electrode is reduced, and current spreading is facilitated. Consequently, the light emission performance of the LED is enhanced.

The disclosure further provides a light-emitting device. The light-emitting device includes a circuit board and at least one light-emitting element located on the circuit board; and each of the at least one light-emitting element includes the LED as described in the disclosure.

As described above, the LED and the light-emitting device of the disclosure can achieve the following technical effects.

In the LED of the disclosure, the projection of the current spreading layer in the direction from the first surface to the second surface does not overlap with the projection of the first electrode in the direction from the first surface to the second surface. In addition, the projection of the current spreading layer in the direction from the first surface to the second surface has the minimum distance from the geometric center of the projection of the pad electrode of the first electrode in the direction from the first surface to the second surface. The projection of the first ohmic contact layer in the direction from the first surface to the second surface is located outside the circumference centered at the geometric center of the projection of the pad electrode in the direction from the first surface to the second surface with the radius of the minimum distance, that is, the first ohmic contact layer is located below the multiple extension strips of the first electrode. By disposing the first ohmic contact layer on the side of the N-type semiconductor layer outside the circumference centered at the geometric center of the projection of the pad electrode in the direction from the first surface to the second surface with the radius of the minimum distance, the area of the first ohmic contact layer is reduced, thereby decreasing the absorption of the light emitted by the active layer. In addition, the above configuration places the first ohmic contact layer below the multiple extension strips of the first electrode, with no first ohmic contact layer beneath the pad electrode. This reduces the current crowding near the pad electrode and facilitates the current spreading. As a result, the light emission performance of the LED is enhanced. Moreover, by not placing the N-type ohmic contact layer beneath the pad electrode, the risk of the pad electrode falling off during the packaging process is reduced, thereby enhancing the reliability of the chip.

### BRIEF DESCRIPTION OF DRAWINGS

FIG. 1 illustrates a top view of an LED according to a first embodiment of the disclosure.

FIG. 2 illustrates a cross-sectional view of the LED shown in FIG. 1 along a direction of a line L1-L1.

FIG. 3 illustrates a cross-sectional view of the LED shown in FIG. 1 along a direction of a line L2-L2.

FIG. 4 illustrates a structural diagram of an LED according to a second embodiment of the disclosure.

FIG. 5 illustrates a flowchart of a preparation method of a LED according to a third embodiment of the disclosure.

FIG. 6 illustrates a schematic diagram of a structure with a semiconductor epitaxial stacked layer formed on a growth substrate.

FIG. 7 illustrates a schematic diagram of a structure with a current spreading layer that is patterned, formed on the structure shown in FIG. 6.

FIG. 8 illustrates a schematic diagram of a structure with a light-transmissive medium layer formed on the structure shown in FIG. 7.

FIG. 9 illustrates a schematic diagram of a structure with a substrate bonded on the structure shown in FIG. 8.

FIG. 10 illustrates a schematic diagram of a structure with a first ohmic contact layer being patterned.

FIG. 11 illustrates a schematic diagram of a structure with a first electrode formed on the structure shown in FIG. 10.

FIG. 12 illustrates a structural diagram of a light-emitting device according to a fourth embodiment of the disclosure.

### DETAILED DESCRIPTION OF EMBODIMENTS

### First Embodiment

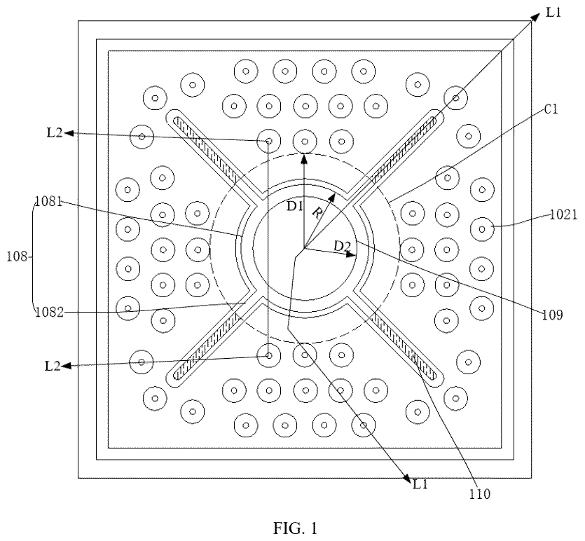

In the first embodiment, an LED is provided. As shown in FIGS. 1-3, the LED in the first embodiment includes a semiconductor epitaxial stacked layer 101, a first electrode 108, a first ohmic contact layer 110 and a current spreading layer 102. The semiconductor epitaxial stacked layer 101 has a first surface 130 and a second surface 120, and the first surface 130 is a light-emitting surface of the LED. The semiconductor epitaxial stacked layer 101 includes an N-type semiconductor layer 1011, an active layer 1013 and a P-type semiconductor layer 1012 in a direction from the first surface 130 to the second surface 120. The first electrode 108 is disposed on the N-type semiconductor layer 1011. The first ohmic contact layer 110 is disposed between the first electrode 108 and the N-type semiconductor layer 1011, and forms an ohmic contact with the N-type semiconductor layer 1011. The current spreading layer 102 is disposed on a side of the P-type semiconductor layer 1012 close to the second surface 102 and has a patterned structure.

Specifically, the semiconductor epitaxial stacked layer 101 can be formed on a growth substrate through methods such as physical vapor deposition (PVD), chemical vapor deposition (CVD), epitaxial growth technology, or atomic layer deposition (ALD). The N-type semiconductor layer 1011 and the P-type semiconductor layer 1012 are semiconductors with different conductive types, electrical properties, and polarities, each providing electrons or holes depending on their respective doping elements. The electrons and the holes can recombine in the active layer 1013 driven by a current, converting electrical energy into light energy to emit light. A wavelength of the light emitted by the LED can be adjusted by changing physical and chemical composition of one or more layers of the active layer 1013.

The active layer 1013 is a region that provides light radiation for electron hole recombination. Different materials can be selected according to a desired emission wavelength. The active layer 1013 can be a single heterostructure (SH), double heterostructure (DH), double-sided double heterostructure (DDH), or a multi-quantum well (MQW) structure. The active layer 1013 includes a well layer and a barrier layer, and the barrier layer has a larger bandgap than the well layer. By adjusting a composition ratio of semiconductor materials in the active layer 1013, light of different wavelengths can be emitted. In the first embodiment, the semiconductor epitaxial stacked layer 101 is capable of emitting light in various wavelength ranges, such as ultraviolet, blue, green, yellow, red, and infrared light. Specifically, a material of the semiconductor epitaxial stacked layer 101 can cover a wavelength range of 200 nanometers (nm) to 950 nm. For example, a gallium nitride (GaN)-based semiconductor epitaxial stacked layer, which is a common nitride material, can be used for wavelengths in a range of 200 nm to 550 nm. The GaN-based semiconductor epitaxial stacked layer often incorporates doping elements such as aluminum (Al) and indium (In). Alternatively, for wavelengths in a range of 550 nm to 950 nm, aluminum gallium indium phosphide (AlGaInP)-based or aluminum gallium arsenide (AlGaAs)-based semiconductor epitaxial stacked layers can be used. To enhance the light-emitting efficiency, a depth of a quantum well, numbers, thicknesses or other characteristics of paired quantum wells and quantum barriers in the active layer 1013 can be modified. In the first embodiment, the semiconductor epitaxial stacked layer 101 is specifically composed of AlGaInP-based or GaAs-based materials.

On the first surface 130 of the semiconductor epitaxial stacked layer 101, that is, on a side of the N-type semiconductor layer 1011, the first electrode 108 is disposed, which is electrically connected to the N-type semiconductor layer 1011. To enhance the current spreading capability of the LED, the first electrode 108 includes a pad electrode 1081 and extension strips 1082. The first electrode 108 can be a single-layer structure, a double-layer structure, or a multi-layer structure. Both the pad electrode 1081 and the extension strips 1082 can be selected from germanium (Ge), gold (Au), nickel (Ni), or any combination thereof. Depending on requirements of subsequent wire bonding, die bonding, or other processes, the pad electrode 1081 can be formed in any suitable location on a chip, such as an edge of the chip or a central region of the chip.

In order to enhance the electrical connection between the first electrode 108 and the N-type semiconductor layer 1011, the first ohmic contact layer 110 is disposed between the first electrode 108 and the N-type semiconductor layer 1011. In the first embodiment, the first ohmic contact layer 110 can be an n-type GaAs layer doped with silicon. Specifically, a thickness of the first ohmic contact layer 110 is in a range of 30 nm to 60 nm, and a silicon doping concentration of the first ohmic contact layer 110 is greater than 1×10¹⁹ cm⁻³.

On the second surface 120 of the semiconductor epitaxial stacked layer 101, that is, on the P-type semiconductor layer 1012, the current spreading layer 102 is disposed. In the first embodiment, a material of the current spreading layer 102 can be GaP, AlGaAs, or AlGaInP. Specifically, the material of the current spreading layer 102 is p-type GaP doped with magnesium (Mg). A Mg doping concentration of the current spreading layer 102 is in a range of 8×10¹⁷ cm⁻³ to 1×10¹⁹ cm⁻³, and a thickness of the current spreading layer 102 is in a range of 0.02 micrometers (μm) to 1.5 μm, further specifically in a range of 0.02 μm to 0.8 μm. Since GaP and GaAs absorb light emitted from the active layer 1013, in order to improve the light emission efficiency of the LED, in the first embodiment, thicknesses of GaP and GaAs material layers are reduced to minimize their light absorption.

When projected in the direction from the first surface 130 to the second surface 120, a top view of the LED of the first embodiment as shown in FIG. 1 is formed. As shown in FIGS. 1 to 3, the first electrode 108 includes the pad electrode 1081 and the extension strips 1082 that are spaced from each other and extend from edges of the pad electrode 1081 in a finger-like manner toward edges of the semiconductor epitaxial stacked layer 101. In a specific embodiment, as shown in FIG. 1, a projection of the LED in the direction from the first surface 130 to the second surface 120 is rectangular or square, and the first electrode 108 includes four extension strips 1082. A projection of the pad electrode 1081 in the direction from the first surface 130 to the second surface 120 is circular, and the four extension strips 1082 extend from the edges of the circular pad electrode 1081 toward four corners of the LED. This allows the four extension strips 1082 to extend as long as possible over the N-type semiconductor layer 1011, thereby diffusing the current to the corners and edges of the LED as much as possible to improve the light emission efficiency. It can be understood that a number and an extension length of the extension strips 1082 can be specifically set according to a specific structure and a size of the LED.

As shown in FIG. 1, in the first embodiment, the current spreading layer 102 has the patterned structure, and the patterned structure is multiple first block-shaped structures 1021 that are separated from each other. A projection of each of the first block-shaped structures 1021 in the direction from the first surface 130 to the second surface 120 is a circular structure, and it can also be an ellipse, a rectangle, a triangle, or other polygonal structure. For illustration purposes, the first embodiment uses the circular structure shown in FIG. 1. As shown in FIG. 1, a projection of the current spreading layer 102 in the direction from the first surface 130 to the second surface 120 does not overlap with a projection of the first electrode 108 in the direction from the first surface 130 to the second surface 120. A projection of the pad electrode 1081 of the first electrode 108 in the direction from the first surface 130 to the second surface 120 has a radius R, and the radius R is in a range of 10 μm to 100 μm, more specifically, in a range of 20 μm to 60 μm. A distance from an edge of the projection of the current spreading layer 102 in the direction from the first surface 130 to the second surface 120 to a geometric center of the projection of the pad electrode 1081 in the direction from the first surface 130 to the second surface 120 is a minimum distance D1, and the minimum distance D1 is in a range of 15 μm to 150 μm, more specifically, in a range of 30 μm to 90 μm. The minimum distance D1 is greater than or equal to the radius R. Specifically, the minimum distance D1 is greater than the radius R, and a difference between the minimum distance D1 and the radius R is in a range of 5 μm to 50 μm, more specifically, in a range of 10 μm to 30 μm.

As shown in FIG. 1, the first ohmic contact layer 110 disposed between the first electrode 108 and the N-type semiconductor layer 1011 is distributed outside a circumference C1, which is centered at the geometric center of the projection of the pad electrode 1081 in the direction from the first surface 130 to the second surface 120 with a radius of the minimum distance D1. Specifically, the first ohmic contact layer 110 is disposed between the extension strips 1082 and the N-type semiconductor layer 1011, outside the circumference C1. This configuration of the first ohmic contact layer 110 reduces an area of the first ohmic contact layer 110, thereby decreasing the absorption of light emitted from the active layer 1013. In addition, the absence of the first ohmic contact layer 110 beneath the pad electrode 1081 minimizes current crowding near the pad electrode 1081, enhancing the uniformity of current spreading and improving the light emission efficiency of the LED. Furthermore, the lack of the first ohmic contact layer 110 under the pad electrode 1081 reduces the risk of the pad electrode 1081 falling off during a packaging process, thereby enhancing the reliability of the chip.

In a specific embodiment, an area of a projection of the circumference C1, which is centered at the geometric center of the projection of the pad electrode 1081 in the direction from the first surface 130 to the second surface 120 with the radius of the minimum distance D1, is 5% to 30% of an area of a projection of the N-type semiconductor layer 1011 in the direction from the first surface 130 to the second surface 120. An area of the projection of the first ohmic contact layer 110 in the direction from the first surface 130 to the second surface 120 is 5% to 30% of an area of the projection of the first electrode 108 in the direction from the first surface 130 to the second surface 120. This configuration ensures that the first ohmic contact layer 110 forms good ohmic contact with the extension strips 1082 of the first electrode 108 while reducing the absorption of light by the first ohmic contact layer 110, thereby improving the light emission efficiency.

As shown in FIG. 1, projections of the multiple first block-shaped structures 1021 in the direction from the first surface 130 to the second surface 120 are separated and distributed around projections of the extension strips 1082 of the first electrode 108 in the direction from the first surface 130 to the second surface 120. On a side of the extension strips 1082 facing towards the pad electrode 1081, the current spreading layer 102 is relatively far away from the extension strips 1082, and on a side of the extensions strips 1082 facing away from the pad electrode 1081, the current spreading layer 102 is relatively close to the extension strips 1082. This configuration enhances the diffusion of the current towards the edges of the LED, prevents current concentration, and improves the uniformity of light emission. In a specific embodiment, an area of the projection of the current spreading layer 102 in the direction from the first surface 130 to the second surface 120 is 5% to 50% of an area of a projection of the P-type semiconductor layer 1012 in the direction from the first surface 130 to the second surface 120. The patterned design of the current spreading layer 102 reduces its light absorption, improves the light emission efficiency of the LED, and ensures that the current spreading layer 102 provides sufficient current diffusion.

In a specific embodiment, a second ohmic contact layer 140 can be disposed below the current spreading layer 102 on the second surface 120 of the semiconductor epitaxial stacked layer 101. The subsequent metal reflective layer forms an ohmic contact with the second ohmic contact layer 140. Specifically, the second ohmic contact layer 140 is disposed below the current spreading layer 102 and can either fully or partially cover the current spreading layer 102. Therefore, the second ohmic contact layer 140 and the current spreading layer 102 are simultaneously patterned, which also reduces the light absorption of the second ohmic contact layer 140. Specifically, the second ohmic contact layer 140 is a transparent conductive layer, which is made of zinc oxide (ZnO), indium oxide (In₂O₃), tin oxide (SnO₂), indium tin oxide (ITO), indium zinc oxide (IZO), gallium-doped zinc oxide (GZO), or any combination thereof. In the first embodiment, the second ohmic contact layer 140 is made of ITO.

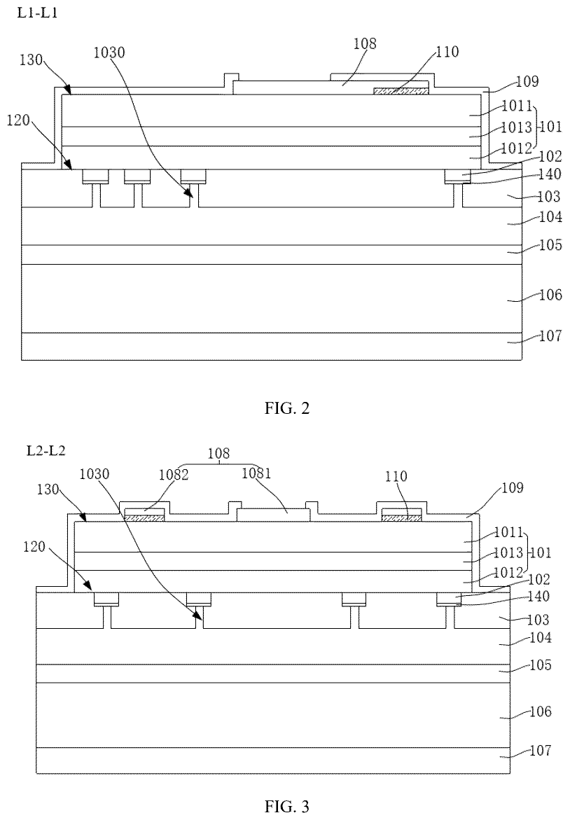

Referring to FIGS. 2 and 3, the LED further includes a light-transmissive medium layer 103, a reflective layer 104, a metal bonding layer 105, a substrate 106, and a second electrode 107.

The light-transmissive medium layer 103 is disposed on a side of the second ohmic contact layer 140 facing away from the second surface 120 and fills regions surrounding the current spreading layer 102. The light-transmissive medium layer 103 has multiple openings above the second ohmic contact layer 140 to define through-holes 1030. The light-transmissive medium layer 103 is composed of at least one material selected from fluorides, oxides, or nitrides, such as ZnO, silicon dioxide (SiO₂), silicon oxide with variable oxygen content (SiOₓ), silicon oxynitride (SiOₓN_{y}), silicon nitride (Si₃N₄), aluminum oxide (Al₂O₃), titanium oxide with variable oxygen content (TiOₓ), magnesium fluoride (MgF), or gallium fluoride (GaF). The light-transmissive medium layer 103 is used to reflect the light radiation from the active layer 1013 back to the semiconductor epitaxial stacked layer 101 or for side-wall light emission. Therefore, the light-transmissive medium layer 103 in direct contact with the semiconductor epitaxial stacked layer 101 is specifically a low-refractive-index material to increase the likelihood of reflection when light radiation passes through the semiconductor epitaxial stacked layer 101 to a surface of the light-transmissive medium layer 103. Specifically, a refractive index of the light-transmissive medium layer 103 is less than 1.5, for example, the light-transmissive medium layer 103 can be SiO₂. A thickness of the light-transmissive medium layer 103 is specifically greater than 100 nm, such as, in a range of 100 nm to 1000 nm, more specifically in a range of 100 nm to 900 nm, or even more specifically in a range of 300 nm to 900 nm. The light transmittance of the light-transmissive medium layer 103 is at least 70%, specifically above 80%, and more specifically above 90%.

Specifically, the light-transmissive medium layer 103 may be composed of a single layer or multiple layers of different materials, or it may be formed by alternately stacking two different types of insulating materials with different refractive indices as described above. More specifically, an optical thickness of the light-transmissive medium layer 103 is an integer multiple of one-fourth of the emission wavelength.

The reflective layer 104 covers the light-transmissive medium layer 103 and extends into the conductive through-holes 1030, making contact with the second ohmic contact layer 140. This configuration ensures electrical conductivity and current spreading within the LED. A cross-sectional area of the second ohmic contact layer 140 is larger than that of the conductive through-holes 1030 in the light-transmissive medium layer 103. This design allows for maximizing the mirror-like reflection area while maintaining a low voltage for the LED, thereby enhancing its light emission brightness and efficiency. The reflective layer 104 has a reflectivity of over 70% and is made of at least one metal or alloy selected from silver (Ag), Ni, Al, rhodium (Rh), palladium (Pd), iridium (Ir), ruthenium (Ru), Mg, titanium (Ti), chromium (Cr), zinc (Zn), platinum (Pt), Au, and hafnium (Hf). In the first embodiment, the reflective layer 104 is specifically made of Au or Ag. This reflective layer 104 reflects the light emitted from the semiconductor epitaxial stacked layer 101 towards the substrate 106 back to the semiconductor epitaxial stacked layer 101, from where it is emitted through the light-emitting surface (i.e., the first surface 130 of the semiconductor epitaxial stacked layer 101).

The conductive through-holes 1030 in the light-transmissive medium layer 103 in cross-section can be any possible shape, such as circular, elliptical, or polygonal. The sidewalls of the conductive through-holes 1030 can be either vertical or tapered. The sidewalls of the conductive through-holes 1030 in the light-transmissive medium layer 103 are tapered to facilitate coverage by the reflective layer 104 on the sidewalls of the openings. In addition, the tapered sidewalls can reflect the light emitted from the semiconductor epitaxial stacked layer 101 towards the light-emitting surface.

Referring to FIG. 2, on a side of the reflective layer 104 facing away from the second surface 120, a substrate 106 is disposed. Between the reflective layer 104 and the substrate 106, there is a metal bonding layer 105. This metal bonding layer 105 bonds the semiconductor epitaxial stacked layer 101 to the substrate 106. The metal bonding layer 105 can be composed of one or more materials such as Au, tin (Sn), Ti, tungsten (W), Ni, Pt, and In. It can be either a single-layer or a multi-layer structure. The substrate 106 is a conductive substrate 106 and can be selected from conductive materials such as a silicon substrate 106, a metal substrate 106, or other conductive substrates 106.

On a side of the substrate 106 facing away from the metal bonding layer 105, a second electrode 107 is disposed, which is configured to cover an entire surface of the substrate 106. A material of the second electrode 107 includes metal materials or metal alloy materials, specifically including Au, Pt, (germanium-aluminum-nickel alloy) GeAlNi, Ti, (Beryllium-Gold alloy) BeAu, germanium-gold alloy (GeAu), Al, or zinc-gold alloy (ZnAu), among others.

Referring to FIG. 2, the LED of the first embodiment also includes a protective layer 109, which covers sidewalls and a portion of the surface of the semiconductor epitaxial stacked layer 101. The protective layer 109 can be composed of SiO₂, SiOₓ, SiOₓN_{y}, Si₃N₄, or a composite material layer of the aforementioned materials. In a specific embodiment, as shown in FIGS. 2 and 3, on the first surface 130, the protective layer 109 covers sidewalls and surface of the extension strips 1082 of the first electrode 108, as well as sidewalls and edge portions of the surface of the pad electrode 1081. A boundary line of a projection of a portion of the protective layer 109 on the pad electrode 1081 is a circular structure with a radius of D2 in the direction from the first surface 130 to the second surface 120, and D1>R>D2. That is, a boundary line of the projection of the pad electrode 1081 in the direction from the first surface 130 to the second surface 120 is located between the boundary line of the projection of the protective layer 109 in the direction from the first surface 130 to the second surface 120 and a boundary line of the circumference C1 centered at the geometric center of the projection of the pad electrode 1082 in the direction from the first surface 130 to the second surface 120 with the radius of the minimum distance D1. The absence of the first ohmic contact layer 110 below the pad electrode 1081 further reduces the area of the first ohmic contact layer 110, minimizing the light absorption. In addition, the lack of the first ohmic contact layer 110 below the pad electrode 1081 reduces the risk of the pad electrode 1081 falling off during the packaging process, enhancing the reliability of the chip.

### Second Embodiment

In the second embodiment, an LED is provided. The LED in the second embodiment also includes a semiconductor epitaxial stacked layer 101, a first electrode 108, a first ohmic contact layer 110 and a current spreading layer 102. The semiconductor epitaxial stacked layer 101 has a first surface 130 and a second surface 120, and the first surface 130 is a light-emitting surface of the LED. The semiconductor epitaxial stacked layer 101 includes an N-type semiconductor layer 1011, an active layer 1013 and a P-type semiconductor layer 1012 in a direction from the first surface 130 to the second surface 120. The first electrode 108 is disposed on the N-type semiconductor layer 1011, and the first ohmic contact layer 110 is disposed between the first electrode 108 and the N-type semiconductor layer 1011 and forms an ohmic contact with the N-type semiconductor layer 1011. The current spreading layer 102 is disposed on a side of the P-type semiconductor layer 1012 close to the second surface 120 and has a patterned structure. The similarities with the first embodiment will not be repeated, and the differences are as follows.

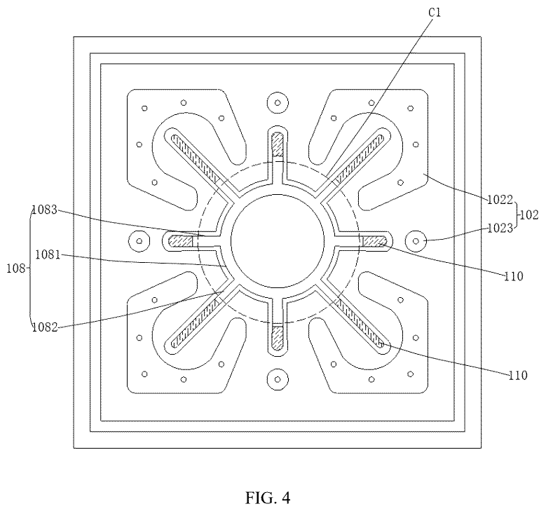

In the second embodiment, as shown in FIG. 4, the current spreading layer 102 has multiple second block-shaped structures 1022 that are separated from each other. Specifically, the multiple second block-shaped structures 1022 are arranged in a one-to-one correspondence with extension strips 1082 of the first electrode 108. A projection of each of the multiple second block-shaped structures 1022 in the direction from the first surface 130 to the second surface 120 is an annular structure with an opening. A projection of a corresponding one of the extension strips 1082 in the direction from the first surface 130 to the second surface 120 extends into the annular structure of the projection of a corresponding one of the plurality of second block-shaped structures in the direction from the first surface to the second surface through the opening of the annular structure, and there is no overlap or intersection between the projections of the extension strips 1082 of the first electrode 108 in the direction from the first surface 130 to the second surface 120 and the projections of the second block-shaped structures 1022 of the current spreading layer 102 in the direction from the first surface 130 to the second surface 120. As shown in FIG. 4, projections of contours of the second block-shaped structures 1022 in the direction from the first surface 130 to the second surface 120 can be irregular shapes. In the second embodiment, the extension strips 1082 of the first electrode 108 extend towards four corners of the LED from the pad electrode 1081 and are surrounded by the second block-shaped structures 1022 of the current spreading layer 102. The second block-shaped structures 1022 have a part of outer contour lines that are parallel to boundary lines of the LED and extend towards the pad electrode 1081. Inner contour lines of the second block-shaped structures 1022 close to the extension strips 1082 can be arc-shaped, and the above contour lines are connected to form a continuous outline. This configuration of the second block-shaped structures 1022 of the current spreading layer 102 allows for better cooperation with the first electrode 108, thereby improving the uniformity of current diffusion.

In a specific embodiment, a distance between an end of each of the extension strips 1082 facing away from the pad electrode 1081 and an inner contour line of a corresponding second block-shaped structure 1022 of the second block-shaped structures 1022 is greater than a distance between a side of each of the extension strips 1082 facing towards the pad electrode 1081 and the inner contour line of the corresponding second block-shaped structure 1022 of the second block-shaped structures 1022. This configuration increases the diffusion of current towards the corners of the LED, thereby improving the uniformity of current diffusion.

In another specific embodiment, as shown in FIG. 4, the first electrode 108 further includes secondary extension strips 1083, and each of the secondary extension strips 1083 is disposed between adjacent two extension strips 1082 of the extension strips 1082. Specifically, a secondary extension strip 1083 is disposed between each two adjacent extension strips 1082 of the extension strips 1082. A number of secondary extension strips 1083 can be selected based on structural characteristics of the light-emitting diode, such as its size. An extension length of each of the secondary extension strips 1083 is less than that of the extension strips 1082, and further, greater than the minimum distance D1. Outside the circumference centered at the geometric center of the pad electrode 1081 with the radius of the minimum distance D1, the first ohmic contact layer 110 is also disposed between the secondary extension strips 1083 and the N-type semiconductor layer 1011.

Specifically, the current spreading layer 102 is disposed in correspondence with the secondary extension strips 1083 and has third block-shaped structures 1023. As shown in FIG. 4, projections of the third block-shaped structures 1023 in the direction from the first surface 130 to the second surface 120 are respectively located on extension lines of projections of the secondary extension strips 1083 in the direction from the first surface 130 to the second surface 120. Contour lines of the third block-shaped structures 1023 and the secondary extension strips 1083 do not overlap or intersect. Similarly, contour lines of the third block-shaped structures 1023 and contour lines of the second block-shaped structures 1022 do not overlap or intersect, and they are distributed at intervals from each other. Shapes of the projections of the third block-shaped structures 1023 in the direction from the first surface 130 to the second surface 120 can be circular, elliptical, triangular, quadrilateral, or other polygonal structures, and can be set according to the structural characteristics of the LED, such as its size.

The provision of the secondary extension strips 1083 increases the current diffusion paths while not significantly increasing the area of the first ohmic contact layer. As a result, the current diffusion capability is enhanced without excessive light absorption, thereby maintaining the light emission efficiency of the LED.

### Third Embodiment

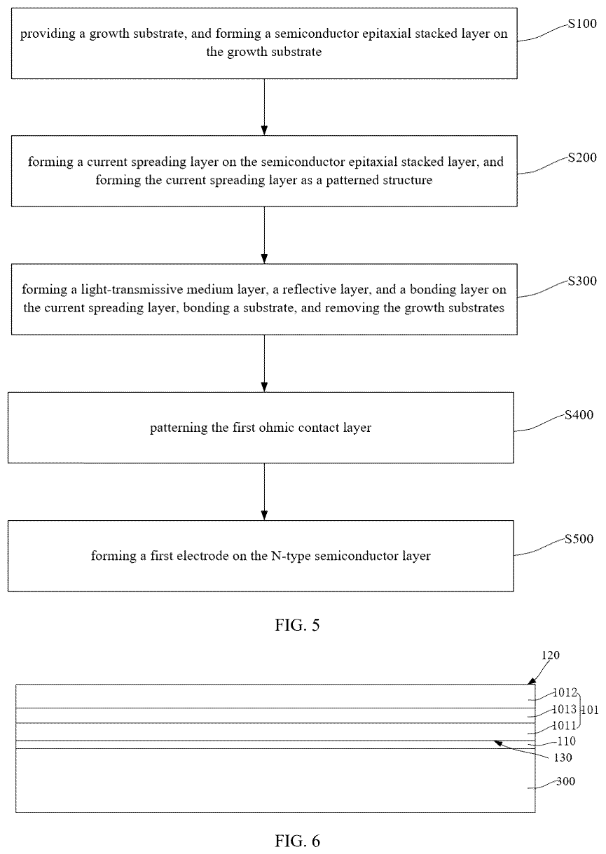

In the third embodiment, a preparation method of an LED is provided. Any one of light emitting diodes in the first and second embodiments can be obtained through the preparation method of the third embodiment. As shown in FIG. 5, the preparation method includes the following steps.

S100, a growth substrate is provided, and a semiconductor epitaxial stacked layer is formed on the growth substrate.

In the third embodiment, the growth substrate can be any substrate suitable for epitaxial growth, such as a silicon substrate, a silicon carbide (SiC) substrate, a GaAs substrate, a sapphire substrate, etc. In the third embodiment, the GaAs substrate is used as an example. As shown in FIG. 6, an N-type semiconductor layer 1011, an active layer 1013, and a P-type semiconductor layer 1012 are sequentially grown on the growth substrate 300 to form the semiconductor epitaxial stacked layer 101. A side of the N-type semiconductor layer 1011 facing towards the growth substrate 300 is a first surface 130 of the semiconductor epitaxial stacked layer 101, and a side of the P-type semiconductor layer 1012 facing away from the growth substrate 300 is a second surface 120 of the semiconductor epitaxial stacked layer 101. A first ohmic contact layer 110 is formed on the side of the N-type semiconductor layer 1011, which can be an n-type GaAs layer doped with silicon. Specifically, a thickness of the first ohmic contact layer 110 is in a range of 30 nm to 60 nm, and a silicon doping concentration of the first ohmic contact layer 110 is greater than 1×10¹⁹ cm⁻³. For details about the semiconductor epitaxial stacked layer 101, reference can be made to the description in the first embodiment, which will not be repeated here.

S200, a current spreading layer is formed on the semiconductor epitaxial stacked layer, and the current spreading layer is formed as a patterned structure.

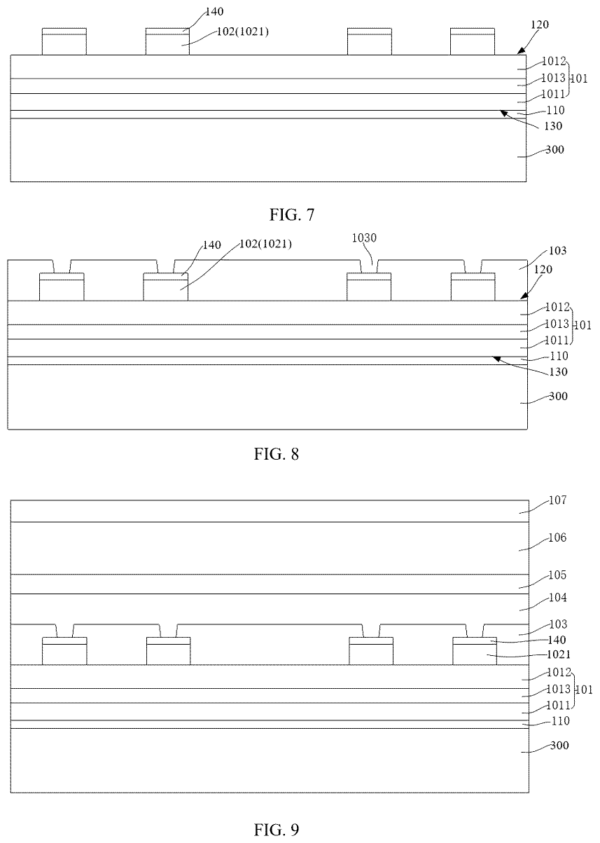

After the semiconductor epitaxial stacked layer 101 is formed, as shown in FIG. 7, the current spreading layer 102 is formed on the second surface 120. A material of the current spreading layer may be GaP, AlGaAs, or AlGaInP. In the third embodiment, the material of the current spreading layer 102 is GaP, and a thickness of the current spreading layer 102 is in a range of 0.02 μm to 1.5 μm. Specifically, the thickness of the current spreading layer 102 is in a range of 0.02 μm to 0.8 μm. A doping concentration of the current spreading layer 102 is in a range of 5×10¹⁷ cm⁻³ to 5×10¹⁸ cm⁻³. Since the GaP has an absorption effect on the light emitted from the active layer 1013, a patterning process is performed on the current spreading layer 102, as shown in FIG. 7. During the patterning process, parts of the current spreading layer 102 are etched away to form first block-shaped structures 1021 that are separated from each other.

S300, a light-transmissive medium layer, a reflective layer, and a bonding layer are formed on the current spreading layer, a substrate is bonded, and the growth substrates is removed.

As shown in FIG. 8, first, a second ohmic contact layer 140 is formed on the patterned current spreading layer 102 shown in FIG. 7. The second ohmic contact layer 140 is formed on the current spreading layer 102 and can completely or partially cover a surface of the current spreading layer 102. Then, a light-transmissive medium layer 103 is formed on the second ohmic contact layer 140. The light-transmissive medium layer 103 covers a surface of the second ohmic contact layer 140 and sidewalls of the second ohmic contact layer 140 and the current spreading layer 102, and fills regions between the current spreading layer 102 and the second ohmic contact layer 140. Then, as shown in FIG. 8, the light-transmissive medium layer 103 is etched in regions corresponding to the second ohmic contact layer 140 to form openings that expose the second ohmic contact layer 140, thereby forming conductive through-holes 1030 that correspond one-to-one with the second ohmic contact layer 140. Subsequently, as shown in FIG. 9, the reflective layer 104 is formed on the light-transmissive medium layer 103. The reflective layer 104 is a metal reflective layer, for example, it can be made of a metal or alloy containing at least one of Ag, Ni, Al, Rh, Pd, Ir, Ru, Mg, Ti, Cr, Zn, Pt, Au, and Hf. The reflective layer 104 covers the light-transmissive medium layer 103 and fills the conductive through-holes 1030 of the light-transmissive medium layer 103 to form an electrical connection with the P-type semiconductor layer 1012 through the second ohmic contact layer 140 and the current spreading layer 102.

Subsequently, as shown in FIG. 9, a bonding layer 105 is formed on the reflective layer 104. The bonding layer 105 is also a metal layer. As shown in FIG. 9, a substrate 106 is bonded on the bonding layer 105. The bonding layer 105 can be composed of any one or a combination of metals such as Au, Sn, Ti, W, Ni, Pt, and In, and the bonding layer 105 can be either a single-layer structure or a multi-layer structure. The substrate 106 is a conductive substrate, which can be selected from conductive materials such as a Si substrate, a metal substrate, or other conductive substrates.

After bonding the substrate 106, a metal layer is deposited on a surface of the substrate 106 to serve as a second electrode 107, and the second electrode 107 is electrically connected to the P-type semiconductor layer 1012.

Subsequently, the growth substrate 300 is removed, and the structure shown in FIG. 9 is inverted such that the first surface 130 of the semiconductor epitaxial stacked layer 101 faces upward, thereby exposing the N-type semiconductor layer 1011.

S400, the first ohmic contact layer is patterned.

S500, a first electrode is formed on the N-type semiconductor layer.

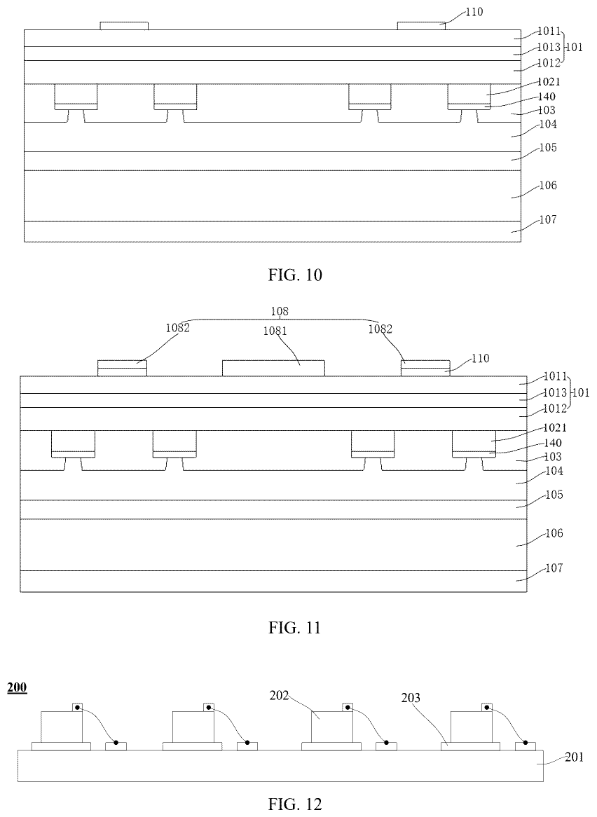

As shown in FIG. 10, the first ohmic contact layer 110 is patterned to form multiple spaced-apart finger-like structures. Then, as shown in FIG. 11, the first electrode 108 is formed on the N-type semiconductor layer 1011, and the first electrode 108 includes a pad electrode 1081 and extension strips 1082 extending from edges of the pad electrode 1081. The extension strips 1082 covers the first ohmic contact layer 110. In a specific embodiment, a projection of the pad electrode 1081 in the direction from the first surface 130 to the second surface 120 is a circular structure. Projections of the extension strips 1082 in the direction from the first surface 130 to the second surface 120 are finger-like structures extending from edges of the circular structure, and a projection of the first ohmic contact layer 110 in the direction from the first surface 130 to the second surface 120 is also in the form of finger-like structure. A projection of the current spreading layer 102 on the side of the P-type semiconductor layer 1012 in the direction from the first surface 130 to the second surface 120 is formed as multiple separated block-shaped structures.

Referring again to FIG. 1, the projection of the current spreading layer 102 in the direction from the first surface 130 to the second surface 120 does not overlap with a projection of the first electrode 108 in the direction from the first surface 130 to the second surface 120. The projection of the pad electrode 1081 of the first electrode 108 in the direction from the first surface 130 to the second surface 120 has a radius R. The radius R is in a range of 10 μm to 100 μm, and more specifically, in a range of 20 μm to 60 μm. A distance from an edge of the projection of the current spreading layer 102 in the direction from the first surface 130 to the second surface 120 to a geometric center of the projection of the pad electrode 1081 in the direction from the first surface 130 to the second surface 120 is a minimum distance D1. The minimum distance D1 is in a range of 15 μm to 150 μm, and more specifically, in a range of 30 μm to 90 μm. The minimum distance D1 is greater than or equal to the radius R. Specifically, the minimum distance D1 is greater than the radius R, and a difference between the minimum distance D1 and the radius R is in a range of 5 μm to 50 μm, and more specifically, in a range of 10 μm to 30 μm.

As shown in FIG. 1, the first ohmic contact layer 110 disposed between the first electrode 108 and the N-type semiconductor layer 1011 is distributed outside a circumference C1, which is centered at the geometric center of the projection of the first electrode 108 in the direction from the first surface 130 to the second surface 120 with a radius of the minimum distance D1 (preferably, the geometric center of the projection of the pad electrode 1081 in the direction from the first surface 130 to the second surface 120). Specifically, the first ohmic contact layer 110 is disposed between the extension strips 1082 and the N-type semiconductor layer 1011, outside the circumference C1. This configuration of the first ohmic contact layer 110 reduces an area of the first ohmic contact layer 110, thereby decreasing the absorption of light emitted from the active layer 1013. In addition, the absence of the first ohmic contact layer 110 below the pad electrode 1081 minimizes current crowding near the electrode pad 1081, enhancing the uniformity of current spreading and improving the light emission efficiency of the LED. Furthermore, the lack of the first ohmic contact layer 110 under the pad electrode 1081 reduces the risk of the electrode pad 1081 falling off during the packaging process, thereby enhancing the reliability of the chip.

In a specific embodiment, an area of a projection of the circumference C1 in the direction from the first surface 130 to the second surface 120, which is centered at the geometric center of the projection of the pad electrode 1082 in the direction from the first surface 130 to the second surface 120 with the radius of the minimum distance D1, is 5% to 30% of an area of a projection of the N-type semiconductor layer 1011 in the direction from the first surface 130 to the second surface 120. An area of the projection of the first ohmic contact layer 110 in the direction from the first surface 130 to the second surface 120 is 5% to 30% of an area of the projection of the first electrode 108 in the direction from the first surface 130 to the second surface 120. This configuration ensures good ohmic contact between the first ohmic contact layer 110 and the extended strips 1082 of the first electrode 108 while reducing the absorption of light by the first ohmic contact layer 110, thereby improving the light emission efficiency.

The third embodiment also includes a step of forming a protective layer, the details of which can be referred to in the description of the first embodiment and will not be repeated here.

In addition, the third embodiment describes the current spreading layer 102 being formed as the first block-shaped structures 1021. It is understood that the current spreading layer 102 may also be formed as second block-shaped structures 1022 and third block-shaped structures 1023 as described in the second embodiment.

### Fourth Embodiment

In the fourth embodiment, a light-emitting device is provided. As shown in FIG. 12, The light-emitting device 200 includes a circuit board 201 and at least one light-emitting element 202 fixed to the circuit board 201. Each of the at least one light-emitting element 202 includes any one or a combination of LEDs described in the above embodiments 1 and 2 of the disclosure. As shown in FIG. 12, an electrode of an LED is directly fixed and connected to a wiring layer 203 of the circuit board 201 through soldering or other processes, and another electrode of the LED is connected to the wiring layer 203 of the circuit board 201 through wire bonding by using a gold wire. Since the light-emitting device includes any one or the combination of the LEDs described in the embodiments 1 and 2, it has good light-emitting performance and better reliability.

The above embodiments are merely illustrative of principles and advantages of the disclosure and are not intended to limit the disclosure. Those skilled in the art can make various modifications and variations without departing from the spirit and scope of the disclosure. Such modifications and variations are within the scope defined by the appended claims.

What is claimed is:

1. A light-emitting diode (LED), comprising:
a semiconductor epitaxial stacked layer, wherein the semiconductor epitaxial stacked layer has a first surface and a second surface that are opposite to each other, the semiconductor epitaxial stacked layer comprises an N-type semiconductor layer, an active layer and a P-type semiconductor layer in a direction from the first surface to the second surface, and the first surface is a light-emitting surface;
a first electrode, disposed on the first surface, wherein the first electrode comprises a pad electrode and a plurality of extension strips, and the plurality of extension strips extend from edges of the pad electrode and are spaced from each other;
a first ohmic contact layer, disposed between the plurality of extension strips and the N-type semiconductor layer, wherein the first ohmic contact layer is covered by the plurality of extension strips; and
a current spreading layer, disposed on the second surface, wherein the current spreading layer has a patterned structure; and
wherein a projection of the current spreading layer in the direction from the first surface to the second surface does not overlap with a projection of the first electrode in the direction from the first surface to the second surface, the projection of the current spreading layer in the direction from the first surface to the second surface has a minimum distance (D1) from a geometric center of a projection of the pad electrode in the direction from the first surface to the second surface, and a projection of the first ohmic contact layer in the direction from the first surface to the second surface is located outside a circumference centered at the geometric center of the projection of the pad electrode in the direction from the first surface to the second surface with a radius of the minimum distance (D1).

2. The LED as claimed in claim 1, wherein the projection of the pad electrode in the direction from the first surface to the second surface is a circle, a radius (R) of the circle is in a range of 10 micrometers (μm) to 100 μm, and the radius (R) of the circle is less than the minimum distance (D1).

3. The LED as claimed in claim 1, wherein the minimum distance (D1) is in a range of 15 μm to 150 μm.

4. The LED as claimed in claim 2, wherein the minimum distance (D1) is in a range of 15 μm to 150 μm, and a difference between the minimum distance (D1) and the radius (R) of the circle is in a range of 5 μm to 50 μm.

5. The LED as claimed in claim 1, wherein the first ohmic contact layer is an n-type gallium arsenide (GaAs) layer doped with silicon, a silicon doping concentration of the first ohmic contact layer is greater than 1×10¹⁹ cm⁻³, and a thickness of the first ohmic contact layer is in a range of 30 nanometers (nm) to 60 nm.

6. The LED as claimed in claim 1, wherein the current spreading layer has a plurality of first block-shaped structures that are separated from each other, projections of the plurality of first block-shaped structures in the direction from the first surface to the second surface are separated and distributed around projections of the plurality of extension strips of the first electrode in the direction from the first surface to the second surface.

7. The LED as claimed in claim 1, wherein the current spreading layer has a plurality of second block-shaped structures that are separated from each other, and the plurality of second block-shaped structures are arranged in a one-to-one correspondence with the plurality of extension strips of the first electrode; and a projection of each of the plurality of second block-shaped structures in the direction from the first surface to the second surface is an annular structure with an opening, and a projection of a corresponding one of the plurality of extension strips in the direction from the first surface to the second surface extends into the annular structure of the projection of a corresponding one of the plurality of second block-shaped structures in the direction from the first surface to the second surface through the opening of the annular structure.

8. The LED as claimed in claim 7, wherein a distance between an end of each of the plurality of extension strips facing away from the pad electrode and an inner contour line of a corresponding second block-shaped structure of the plurality of second block-shaped structures is greater than a distance between a side of each of the plurality of extension strips facing towards the pad electrode and the inner contour line of the corresponding second block-shaped structure of the plurality of second block-shaped structures.

9. The LED as claimed in claim 7, wherein the first electrode further comprises secondary extension strips, and each of the secondary extension strips is disposed between adjacent two extension strips of the plurality of extension strips.

10. The LED as claimed in claim 9, wherein the current spreading layer further comprises third block-shaped structures, and the third block-shaped structures are arranged in a one-to-one correspondence with the secondary extension strips.

11. The LED as claimed in claim 10, wherein projections of the third block-shaped structures in the direction from the first surface to the second surface are respectively located on extension lines of projections of the secondary extension strips in the direction from the first surface to the second surface, and are spaced from the projections of the secondary extension strips in the direction from the first surface to the second surface and projections of the plurality of second block-shaped structures in the direction from the first surface to the second surface.

12. The LED as claimed in claim 10, wherein projections of a plurality of first block-shaped structures in the direction from the first surface to the second surface and the projections of the third block-shaped structures in the direction from the first surface to the second surface are circular, elliptical, or polygonal.

13. The LED as claimed in claim 9, wherein a length of a projection of each of the secondary extension strips in the direction from the first surface to the second surface is less than a length of a projection of each of the plurality of extension strips in the direction from the first surface to the second surface.

14. The LED as claimed in claim 1, wherein an area of a projection of the circumference with the radius of the minimum distance (D1) in the direction from the first surface to the second surface is 5% to 30% of an area of a projection of the N-type semiconductor layer in the direction from the first surface to the second surface.

15. The LED as claimed in claim 1, wherein an area of the projection of the first ohmic contact layer in the direction from the first surface to the second surface is 5% to 30% of an area of the projection of the first electrode in the direction from the first surface to the second surface, and an area of the projection of the current spreading layer in the direction from the first surface to the second surface is 5% to 50% of an area of a projection of the P-type semiconductor layer in the direction from the first surface to the second surface.

16. The LED as claimed in claim 1, wherein the current spreading layer is relatively far away from the plurality of extension strips on a side of the plurality of extension strips facing towards the pad electrode, and the current spreading layer is relatively close to the plurality of extension strips on a side of the plurality of extension strips facing away from the pad electrode.

17. The LED as claimed in claim 1, wherein the LED further comprises a protective layer disposed on the first surface, the protective layer covers the first surface and at least part of the pad electrode is exposed from the protective layer, and a boundary line of the projection of the pad electrode in the direction from the first surface to the second surface is located between a boundary line of a projection of the protective layer in the direction from the first surface to the second surface and a boundary line of the circumference centered at the geometric center of the projection of the pad electrode in the direction from the first surface to the second surface with the radius of the minimum distance (D1).

18. The LED as claimed in claim 1, wherein the LED further comprises:
a second ohmic contact layer, disposed on a side of the current spreading layer facing away from the second surface;
a light-transmissive medium layer, disposed on a side of the second ohmic contact layer facing away from the semiconductor epitaxial stacked layer, wherein the light-transmissive medium layer has a plurality of openings to define a plurality of conductive through-holes;
a reflective layer, disposed below the light-transmissive medium layer, wherein the reflective layer is filled with the multiple conductive through-holes to form an electrical connection with the second ohmic contact layer;
a substrate, disposed on a side of the reflective layer facing away from the second surface;
a metal bonding layer, disposed between the substrate and the reflective layer; and
a second electrode, disposed on a side of the substrate facing away from the second surface and electrically connected to the P-type semiconductor layer.

19. The LED as claimed in claim 18, wherein a refractive index of the light-transmissive medium layer is less than 1.5, and a thickness of the light-transmissive medium layer is greater than 100 nm.

20. A light-emitting device, wherein the light-emitting device comprises a circuit board, and at least one light-emitting element located on the circuit board; and each of the at least one light-emitting element comprises the LED as claimed in claim 1.
